(19) United States
(12) Patent Application Publication
(10) Pub. No.: US 2026/0107851 A1
(43) Pub. Date: Apr. 16, 2026

(54) SEMICONDUCTOR MODULE

(71) Applicant: FUJI ELECTRIC CO., LTD., Kawasaki-shi (JP)

(72) Inventor: Kazuma KAWAMURA, Kawasaki-shi (JP)

(73) Assignee: FUJI ELECTRIC CO., LTD., Kawasaki-shi (JP)

(21) Appl. No.: 19/307,501

(22) Filed: Aug. 22, 2025

(30) Foreign Application Priority Data
Oct. 16, 2024 (JP) 2024-180528

(51) Int. Cl. H01L 23/498; H01L 23/043

(52) U.S. Cl. CPC H10W 90/701; H10W 76/13

(57) ABSTRACT

A semiconductor module includes: semiconductor elements; wiring boards on which these semiconductor elements are mounted; terminals that are electrically connected to these wiring boards; a case that houses the semiconductor elements and the wiring boards. The case includes case through-holes into which these terminals are inserted such that root portions of the terminals respectively protrude from the case through-holes outside the case. The semiconductor module further includes auxiliary blocks that sandwich the root portions with the case to fix the terminals to the case; and a sealing material that closes gaps between the terminals and the case through-holes together with the auxiliary blocks and adheres the auxiliary blocks to the case.

### CROSS-REFERENCE TO RELATED APPLICATIONS

This application is based upon and claims the benefit of priority to Japanese Patent Application No. 2024-180528, filed on Oct. 16, 2024, the entire contents of which are incorporated herein by reference.

### BACKGROUND OF THE INVENTION

### 1. Technical Field

The present invention relates to a semiconductor module including a case that houses semiconductor elements and wiring boards.

### 2. Description of the Related Art

Typically, as a semiconductor module used for a power conversion device or the like, semiconductor modules or the like have been known that each include a case that houses semiconductor elements and wiring boards (see, for example refer to JP 2023-088099 A, JP 2022-081337 A, and WO 2024/057752 A). The semiconductor module of these types include a semiconductor module in which terminals such as main terminals or auxiliary terminals are insert-molded with a case, a semiconductor module in which a case is disposed such that terminals are inserted into through-holes of the case, and the like.

### SUMMARY OF THE INVENTION

According to a configuration where terminals are inserted into through-holes of a case, gaps are produced between the terminals and the through-holes. However, narrow intervals between terminals make it difficult to approach a dispenser that supplies a sealing material that fills the gaps. Furthermore, failures due to unintended adhesion of the sealing material to the terminals or contact of the dispenser with the terminals occurs in a process of handling the dispenser. If the gaps between the terminals and the through-holes cannot be closed, a corrosive gas (such as hydrogen sulfide or sulfuric acid gas) flows in.

According to one aspect, an object of the present invention is to provide a semiconductor module that can prevent an inflow of a corrosive gas from gaps between terminals and a case.

According to one aspect, a semiconductor module includes: a semiconductor element; a wiring board on which the semiconductor element has been mounted; a terminal that has been electrically connected to the wiring board; a case that includes a case through-hole into which the terminal has been inserted and houses the semiconductor element and the wiring board; an auxiliary block that sandwiches a root portion of the terminal protruding from the case through-hole to an outside, and is fixed to the case; and a sealing material that closes a gap between the terminal and the case through-hole together with the auxiliary block, and adheres the auxiliary block to the case.

According to the above aspect, it is possible to prevent an inflow of a corrosive gas from gaps between terminals and a case.

### BRIEF DESCRIPTION OF THE DRAWINGS

FIG. 1 is a perspective view illustrating a semiconductor module according to one embodiment;

FIG. 2 is a plan view illustrating the semiconductor module according to one embodiment;

FIG. 3 is a front view illustrating the semiconductor module before arrangement of a case according to one embodiment;

FIG. 4 is a circuit diagram of the semiconductor module according to one embodiment;

FIG. 5 is a cross-sectional view taken along line V-V in FIG. 2;

FIG. 6 is a cross-sectional view taken along line VI-VI in FIG. 2;

FIG. 7A is a perspective view (part 1) for explaining arrangement of auxiliary blocks according to one embodiment;

FIG. 7B is a perspective view (part 2) for explaining the arrangement of the auxiliary blocks according to one embodiment;

FIG. 8A is a perspective view (part 1) for explaining the arrangement of the auxiliary blocks according to a first modification of one embodiment;

FIG. 8B is a perspective view (part 2) for explaining the arrangement of the auxiliary blocks according to the first modification of one embodiment;

FIG. 9A is a perspective view (part 1) for explaining arrangement of auxiliary blocks according to a second modification of one embodiment;

FIG. 9B is a perspective view (part 2) for explaining the arrangement of the auxiliary blocks according to the second modification of one embodiment;

FIG. 9C is a perspective view (part 3) for explaining the arrangement of the auxiliary blocks according to the second modification of one embodiment;

FIG. 10A is a perspective view (part 1) for explaining arrangement of auxiliary blocks according to a third modification of one embodiment;

FIG. 10B is a perspective view (part 2) for explaining the arrangement of the auxiliary blocks according to the third modification of one embodiment;

FIG. 11A is a perspective view (part 1) for explaining arrangement of auxiliary blocks according to a fourth modification of one embodiment; and

FIG. 11B is a perspective view (part 2) for explaining the arrangement of the auxiliary blocks according to the fourth modification of one embodiment.

### DETAILED DESCRIPTION

Hereinafter, a semiconductor module 1 according to one embodiment of the present invention will be described in detail with reference to the drawings. Note that each axis of X, Y, and Z in each figure to be referred is illustrated for the purpose of defining a direction or each plane in the illustrated semiconductor module 1 or the like. The X, Y, and Z axes are orthogonal to each other and form a right-handed system. In the following description, a Z direction may be referred to as a vertical direction. Furthermore, a surface including the X axis and the Y axis may be referred to as an upper surface or a lower surface. Such directions and planes are terms used for convenience of description. Thus, depending on an attachment posture of the semiconductor module 1 or the like, a correspondence relationship with the X, Y, and Z directions may vary. For example, here, a surface facing a Z direction positive side (+Z direction) in a member forming the semiconductor module 1 is referred to as an upper surface, and a surface facing a Z direction negative side (−Z direction) is referred to as a lower surface. However, the surface facing the Z direction negative side may be referred to as the upper surface, and the surface facing the Z direction positive side may be referred to as the lower surface. Furthermore, here, the plan view means a case where the upper surface (XY plane) of the semiconductor module 1 or the like is viewed in a perspective manner from the Z direction positive side toward the Z direction negative side.

An aspect ratio and a magnitude relationship between respective members in each figure are merely schematically represented, and do not necessarily coincide with a relationship in the semiconductor module 1 or the like actually manufactured. For convenience of description, there is a case where the magnitude relationship between the members may be exaggerated. Furthermore, the shapes of the same members may be different between different drawings.

In the following description, as an example of the semiconductor module 1 according to one embodiment, a device that is applied to a power conversion device such as an inverter device of an industrial or an in-vehicle motor will be cited. Therefore, in the following description, detailed description of the same or similar configuration, function, operation, assembly method, and the like as or to those of a known semiconductor module will be omitted.

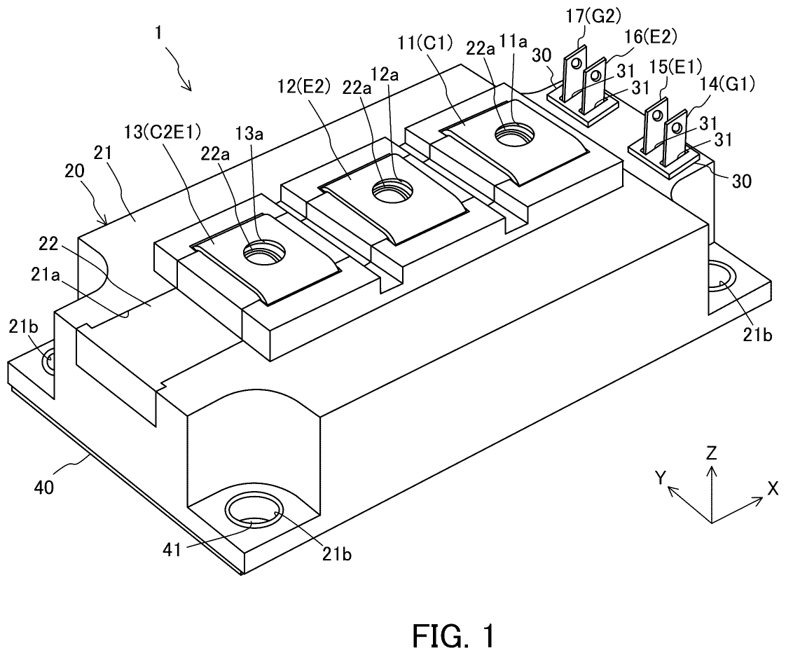

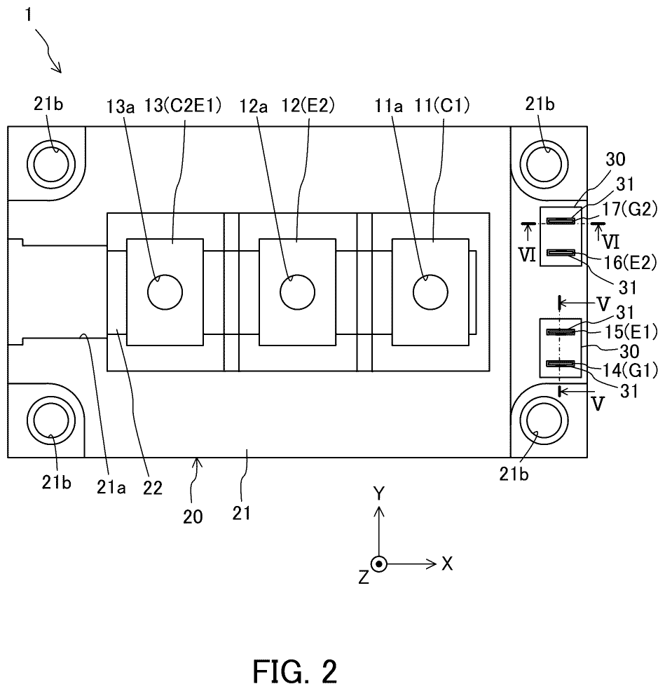

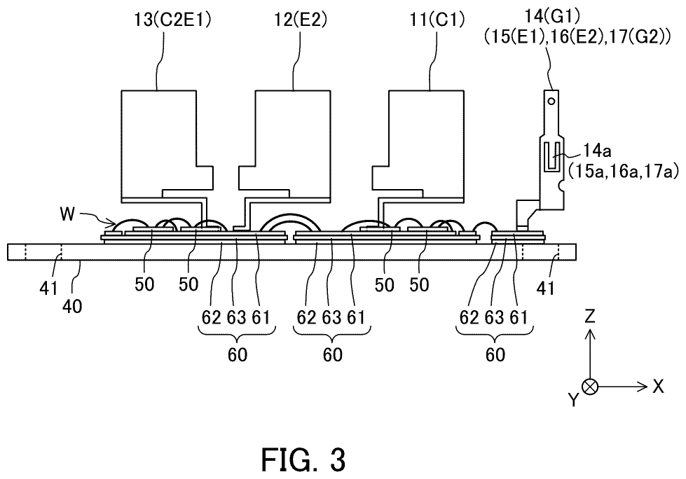

FIG. 1 is a perspective view illustrating the semiconductor module 1. FIG. 2 is a plan view illustrating the semiconductor module 1. FIG. 3 is a front view illustrating the semiconductor module 1 before arrangement of a case 20.

The semiconductor module 1 illustrated in FIGS. 1 and 2 includes main terminals 11 to 13, auxiliary terminals 14 to 17, the case 20, two auxiliary blocks 30, a heat dissipation base 40 (see FIGS. 1 and 3), a plurality of semiconductor elements 50 (see FIG. 3), and a plurality of wiring boards 60 (see FIG. 3).

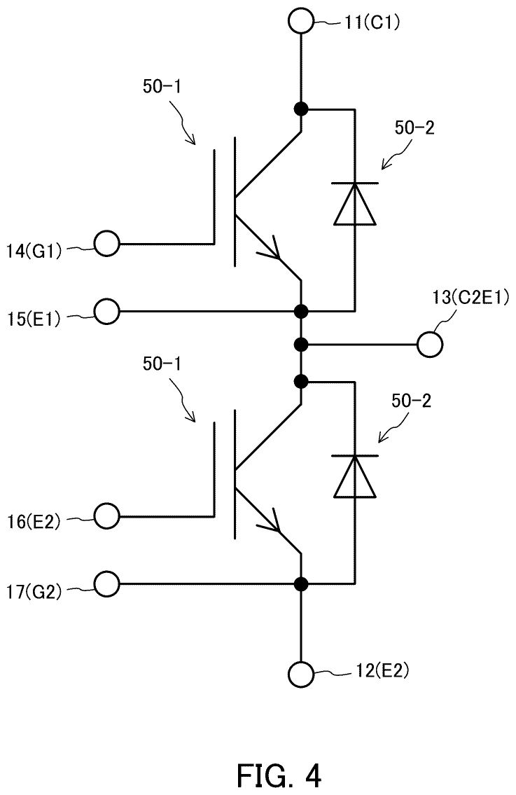

Each of the main terminals 11 to 13 is a metal member having a downward U-shaped plate-like shape, and is electrically connected to the wiring board 60 by bonding two portions of the lower end to the wiring board 60 to be described later with a solder or the like. The main terminals 11 to 13 are input terminals or output terminals of the semiconductor module 1, and a main current flows therethrough. As also illustrated in FIG. 4, for example, the main terminal 11 is a C1 terminal, the main terminal 12 is an E2 terminal, and the main terminal 13 is a C2E1 terminal.

The main terminals 11 to 13 include main terminal through-holes 11a, 12a, and 13a, respectively, at upper ends. Screws of unillustrated external terminals are inserted into these main terminal through-holes 11a, 12a, and 13a. The main terminals 11 to 13 are disposed such that only upper surface portions are exposed from the case 20.

Each of the auxiliary terminals 14 to 17 is a plate-like metal member that is electrically connected to the wiring board 60 by bonding a lower end thereof to the wiring board 60 with a solder or the like, penetrates the case 20, and protrudes to the outside of the case 20 in a single protrusion direction (Z direction positive side). The auxiliary terminals 14 to 17 are terminals such as control terminals through which a main current does not flow. As also illustrated in FIG. 4, for example, the auxiliary terminal 14 is a G1 terminal, the auxiliary terminal 15 is an E1 terminal, the auxiliary terminal 16 is an E2 terminal, and the auxiliary terminal 17 is a G2 terminal.

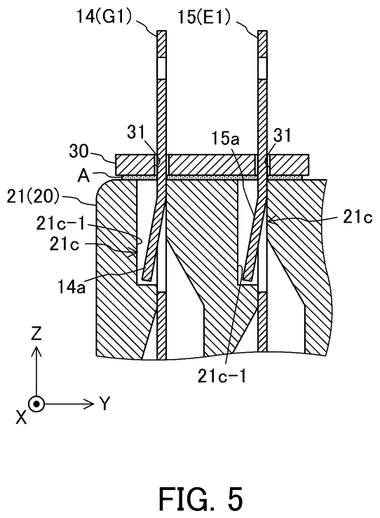

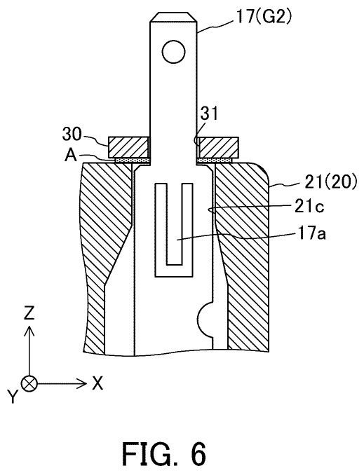

The auxiliary terminals 14 to 17 include protrusions 14a, 15a, 16a, and 17a, respectively, whose surroundings have been removed in U shapes. The protrusions 14a and 15a protrude toward a Y direction negative side, and the protrusions 16a and 17a protrude toward a Y direction positive side. Note that a Y direction that is a protrusion direction of these protrusions 14a to 17a is an example of a direction intersecting the Z direction that is a penetration direction (extension direction) in which the auxiliary terminals 14 to 17 penetrate case through-holes 21c illustrated in FIGS. 5 and 6. As illustrated in FIG. 5, the protrusions 14a to 17a are housed in bulging parts 21c-1 of the case through-holes 21c. This bulging part 21c-1 bulges over an opening portion of the case through-hole 21c in the upper surface of a main body 21.

The case 20 is formed using, for example, a thermoplastic resin material such as Poly Phenylene Sulfide (PPS) or Poly Amide (PA), and has the insulating property. The case 20 includes the main body 21 and a nut globe 22 that is disposed in the opening part 21a of this main body 21 and fixes screws of the above-described external terminals to the main terminals 11 to 13.

For example, the case 20 is fixed to an edge of the upper surface of the heat dissipation base 40 by adhesion on the lower surface of the main body 21. Fastening holes 21b for fixing the case 20 to an unillustrated cooler together with the heat dissipation base 40 are provided at four corners of the case 20 (main body 21) in plan view. Furthermore, the main body 21 of the case 20 includes the four case through-holes 21c into which the auxiliary terminals 14 to 17 have been inserted, and houses the semiconductor elements 50 and the wiring boards 60.

As illustrated in FIG. 1, the nut globe 22 includes nuts 22a at positions meeting the main terminals 11 to 13. As illustrated in FIG. 3, the main body 21 is placed above the semiconductor elements 50 and the wiring boards 60 such that the main terminals 11 to 13 and the auxiliary terminals 14 to 17 bonded to the wiring boards 60 are exposed to the outside, and then the nut globe 22 is inserted from an end portion on an X direction negative side to an X direction positive side of the opening part 21a of the main body 21. Thus, in a state where the nut globe 22 sandwiches the main terminals 11 to 13 between the nut globe 22 and a sidewall of the opening part 21a, the nuts 22a of the nut globe 22 are located below the main terminal through-holes 11a, 12a, and 13a of the main terminals 11 to 13.

The heat dissipation base 40 has a rectangular shape in plan view. The heat dissipation base 40 includes fastening holes 41 provided at four corners in plan view. The heat dissipation base 40 is fastened to the unillustrated cooler together with the case 20 by screws to be inserted into the fastening holes 41 (indicated by broken lines that are hidden lines in in FIG. 3).

The heat dissipation base 40 is a member that functions as a heat conducting member that conducts heat generated by the semiconductor elements 50 to the cooler, and is formed of, for example, a metal plate such as a copper plate or an aluminum plate.

The semiconductor element 50 is mounted on the wiring board 60. For example, the semiconductor element 50 is an Insulated Gate Bipolar Transistor (IGBT) that is a switching element 50-1 illustrated in FIG. 4, a Free Wheeling Diode (FWD) element that is a diode element 50-2, or the like. As the semiconductor element 50, another semiconductor element such as a Reverse Conducting (RC)-IGBT element in which the switching element 50-1 and the diode element 50-2 connected in antiparallel to this switching element 50-1 are integrated may be disposed. The switching element 50-1 and the diode element 50-2 in the semiconductor element 50 are not limited to be formed on a Si substrate, and may be formed on a semiconductor substrate using a wide band gap semiconductor such as Silicon Carbide (SiC) or Gallium Nitride (GaN), for example. Furthermore, the switching element 50-1 may include, for example, a SiC-Metal Oxide Semiconductor Field Effect Transistor (MOSFET), a Bipolar Junction Transistor (BJT), or the like. Furthermore, the diode element 50-2 may include, for example, a SiC-Schottky Barrier Diode (SBD), a Junction Barrier Schottky (JBS) diode, a Merged PN Schottky (MPS) diode, a PN diode, or the like.

The semiconductor element 50 is bonded to the first conductor layer 61 of the wiring board 60, and is directly or indirectly electrically connected to the other semiconductor elements 50, the first conductor layers 61 of the wiring boards 60, the main terminals 11 to 13, the auxiliary terminals 14 to 17, and the like by wirings W. The wiring W is, for example, a metallic bonding wire. The wiring W may be replaced with another wiring such as a lead formed by machining a metal plate such as a copper plate.

The plurality of wiring boards 60 are bonded to the single common heat dissipation base 40 with a bonding material such as a solder on the lower surface (second conductor layer 62). The wiring board 60 has a rectangular shape in plan view and includes the first conductor layer 61, the second conductor layer 62, and an insulating layer 63. The wiring board 60 may be, for example, a Direct Copper Bonding (DCB) substrate or an Active Metal Brazing (AMB) substrate. The wiring board 60 may be referred to as a laminated substrate, an insulating circuit substrate, an insulating heat dissipation circuit substrate, or the like.

The first conductor layer 61 is, for example, a member that functions as a wiring member in an inverter circuit and is provided to be separated as a plurality of parts as a metal plate, a metal foil, or the like of copper, aluminum, or the like on the upper surface of the insulating layer 63. The first conductor layer 61 is electrically connected to the other first conductor layers 61, the semiconductor elements 50, the main terminals 11 to 13, the auxiliary terminals 14 to 17, and the like by the wirings W. The first conductor layer 61 may be referred to as a conductor plate, a conductor pattern, a conductive layer, a wiring pattern, or the like.

The second conductor layer 62 is, for example, a member that functions as a heat conducting member that conducts heat generated in the inverter circuit to the heat dissipation base 40 and is provided as a metal plate, a metal foil, or the like of copper, aluminum, or the like on the lower surface of the insulating layer 63. The second conductor layer 62 (wiring board 60) is bonded to the heat dissipation base 40 with the bonding material such as a solder. The second conductor layer 62 may be referred to as a heat dissipation layer, a heat dissipation plate, a heat dissipation pattern, a conductor pattern, or the like.

The insulating layer 63 is, for example, a ceramic substrate. Although the insulating layer 63 is not limited to a specific substrate, the insulating layer 63 may be, for example, a ceramic substrate formed of a ceramic material such as aluminum nitride (AlN), aluminum oxide (Al₂O₃), silicon nitride (Si₃N₄), or a composite material of aluminum oxide (Al₂O₃) and zirconium oxide (ZrO₂). The insulating layer 63 may be, for example, a substrate obtained by molding an insulating resin such as an epoxy resin, a substrate obtained by impregnating a base material such as a glass fiber with an insulating resin, a substrate obtained by coating a surface of a flat plate-like metal core with an insulating resin, or the like.

Note that the shapes, the number of arrangement, arrangement locations, and the like of the main terminals 11 to 13, the auxiliary terminals 14 to 17, the semiconductor elements 50, and the wiring boards 60 can be appropriately changed. It is desirable that the pluralities of the main terminals 11 to 13, the auxiliary terminals 14 to 17, the semiconductor elements 50, and the wiring boards 60 are disposed. However, the numbers of the semiconductor elements 50 and the wiring boards 60 in particular can be any number. Furthermore, the semiconductor elements 50 and the wiring boards 60 are preferably sealed with a sealing material such as an epoxy resin or a silicone gel.

The auxiliary block 30 has, for example, a thin plate shape. The auxiliary block 30 may have a thick shape such as a cubic shape, but is desirably a thin member. The auxiliary block 30 includes two block through-holes 31. One of the auxiliary terminals 14 to 17 is inserted into the block through-hole 31. One of the two auxiliary blocks 30 sandwiches root portions of the auxiliary terminals 14 and 15 protruding from the case through-holes 21c of the case 20 to the outside. Furthermore, the other one of the two auxiliary blocks 30 sandwiches root portions of the auxiliary terminals 16 and 17 protruding from the case through-holes 21c of the case 20 to the outside.

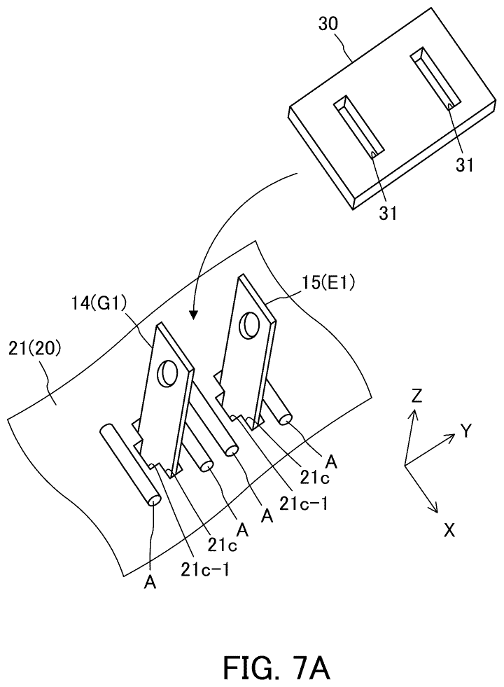

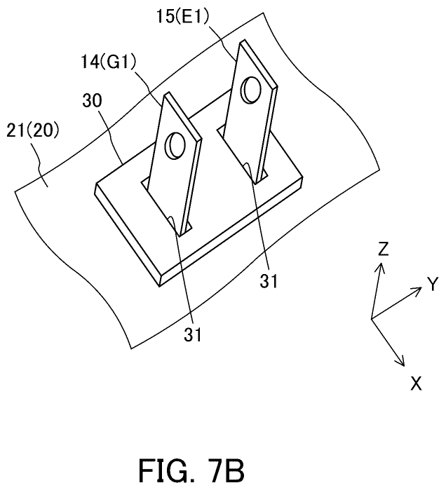

As illustrated in FIG. 7A, after the case 20 (main body 21) is disposed, the auxiliary blocks 30 are preferably fixed to the case 20 by pushing and spreading an adhesive A that is an example of a sealing material disposed in the surroundings of the case through-holes 21c on the upper surface of the main body 21. By disposing the adhesive A between the auxiliary blocks 30 and the case 20 in this way, the adhesive A closes gaps between the auxiliary terminals 14 and 15 or the auxiliary terminals 16 and 17 and the case through-holes 21c of the case 20 together with the auxiliary block 30 as illustrated in FIG. 7B, and fixes the auxiliary block 30 to the case 20 (main body 21). Note that part of the pushed and spread adhesive A may enter the case through-holes 21c or the block through-holes 31.

The adhesive A is, for example, a silicone-based adhesive, has an arbitrary shape such as a rod shape, and is disposed on the main body 21. Note that, although the adhesive A is separated into a plurality of adhesives and disposed in the example of FIG. 7A, the adhesive A having another shape such as a sheet shape provided with through-holes through which the auxiliary terminals 14 to 17 penetrate may be disposed. The adhesive A only needs to be disposed in the surroundings of the case through-holes 21c on the upper surface of the case 20 (main body 21), so that it is unnecessary to finely handle the dispenser compared to an aspect where the adhesive A is disposed inside the case through-holes 21c so as to close between the case through-holes 21c and the auxiliary terminals 14 to 17. Note that, instead of the adhesive A, a sealing material and an adhesive may be disposed, a sealing material having no adhesiveness may be disposed between the case 20 and the auxiliary blocks 30, or the auxiliary blocks 30 may be fixed to the case 20 by another means such as fitting. However, by using the adhesive A as the sealing material, it is possible to fix the case 20 and the auxiliary blocks 30 while closing the gaps between the auxiliary terminals 14 to 17 and the case through-holes 21c.

Furthermore, the auxiliary block 30 may include only the single block through-hole 31 into which any one of the auxiliary terminals 14 to 17 is inserted such that the root portion is sandwiched. In this case, the auxiliary blocks 30 the number of which is the same as the number of the auxiliary terminals 14 to 17 are disposed. Furthermore, the auxiliary block 30 may include the three or more block through-holes 31. Furthermore, in the block through-holes 31 of the auxiliary block 30, not the auxiliary terminals 14 to 17, but main terminals or the like in a case where the main terminals or the like are disposed so as to penetrate the case 20 may be inserted.

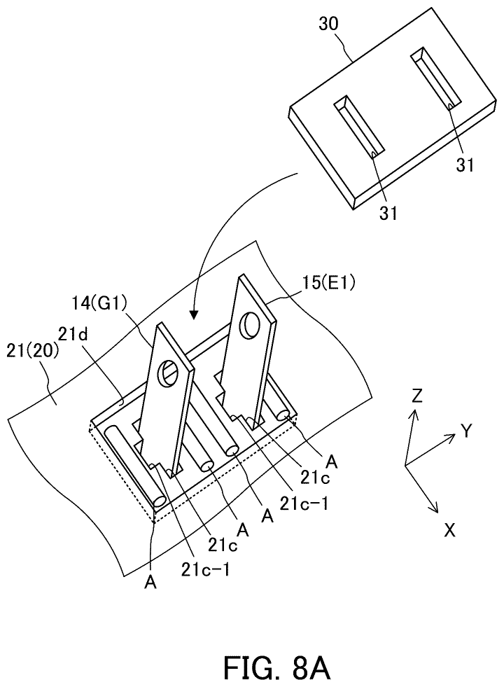

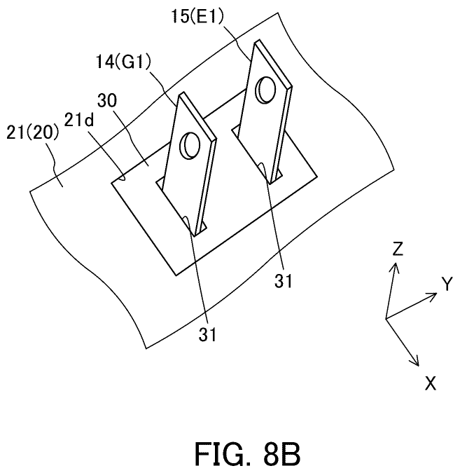

As illustrated in FIG. 8A (first modification), the case 20 (main body 21) is preferably provided with a recess part 21d into which the auxiliary block 30 is inserted in a penetration direction (Z direction) in which the auxiliary terminals 14 to 17 penetrate the case through-holes 21c. In this case, as illustrated in FIG. 8B, the auxiliary blocks 30 do not protrude from the main body 21, and it is possible to increase protrusion lengths of the auxiliary terminals 14 to 17 from the main body 21. Note that the recess part 21d of the case 20 (main body 21) may be a recess part into which part of the auxiliary block 30 is inserted.

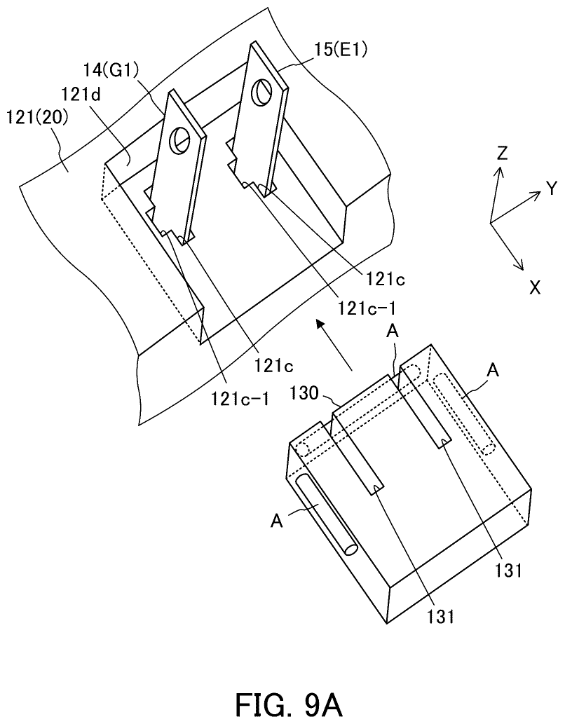

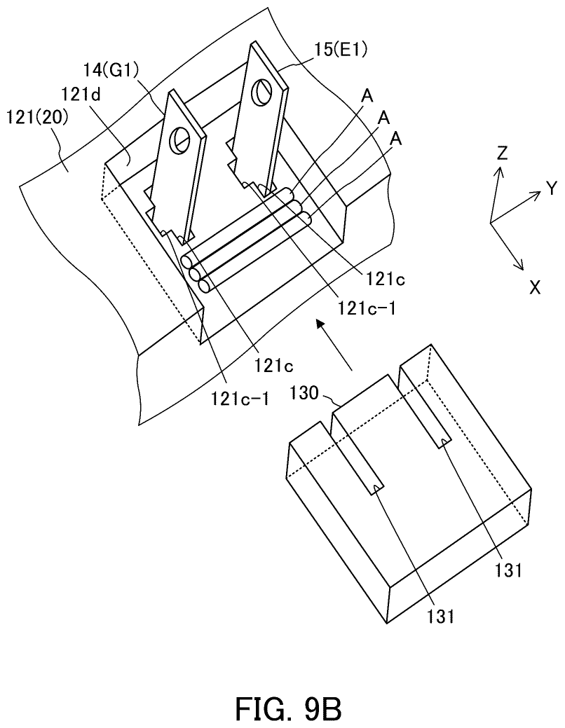

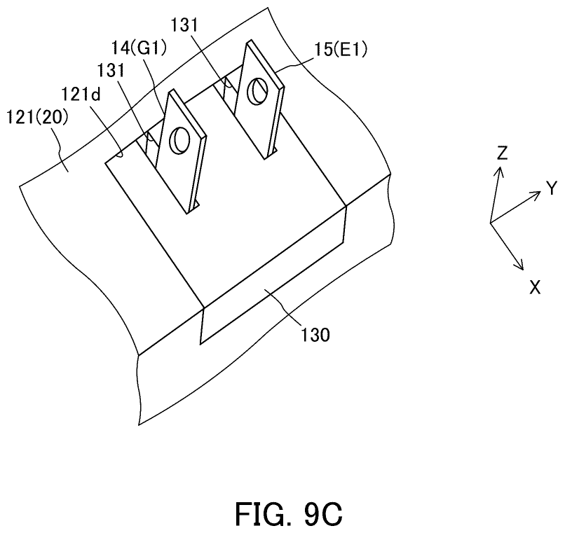

As illustrated in FIG. 9A (second modification), an auxiliary block 130 may include two block cutouts 131 instead of the two block through-holes 31 of the above-described auxiliary block 30. In this case, one of the auxiliary terminals 14 to 17 is inserted into the block cutout 131 such that the root portion is sandwiched. Furthermore, a main body 121 (case 20) may include a case cutout 121d instead of the recess part 21d. In this case, the auxiliary block 130 is inserted into the X direction negative side of the case cutout 121d, and the auxiliary block 130 does not protrude from the main body 121 as illustrated in FIG. 9C.

Note that part of the auxiliary block 30 may be inserted into the case cutout 121d of the case 20 (main body 121). Furthermore, the X direction negative side that is the insertion direction of the auxiliary block 130 is an example of a direction intersecting the penetration direction (Z direction) in which the auxiliary terminals 14 to 17 penetrate case through-holes 121c. Furthermore, the case through-hole 121c is also preferably provided with a bulging part 121c-1. Furthermore, the auxiliary block 130 may include the single or three or more block cutouts 131 into which any one of the auxiliary terminals 14 to 17 is inserted. Furthermore, not the auxiliary terminals 14 to 17 but the main terminals or the like in a case where main terminals or the like in a case where the main terminals or the like are disposed so as to penetrate the case 20 may be inserted into the block cutouts 131 of the auxiliary block 130.

The adhesive A may be disposed on the auxiliary block 130 (e.g., side surfaces) as illustrated in FIG. 9A, may be disposed in the case cutout 121d (e.g., bottom surface) as illustrated in FIG. 9B, or may be disposed on both the auxiliary block 130 and the case cutout 121d. In particular, it is desirable that the adhesive A is disposed at an end part on an insertion direction distal end side (X direction negative side) of the auxiliary block 130, and is disposed on the bottom surface of the case cutout 121d.

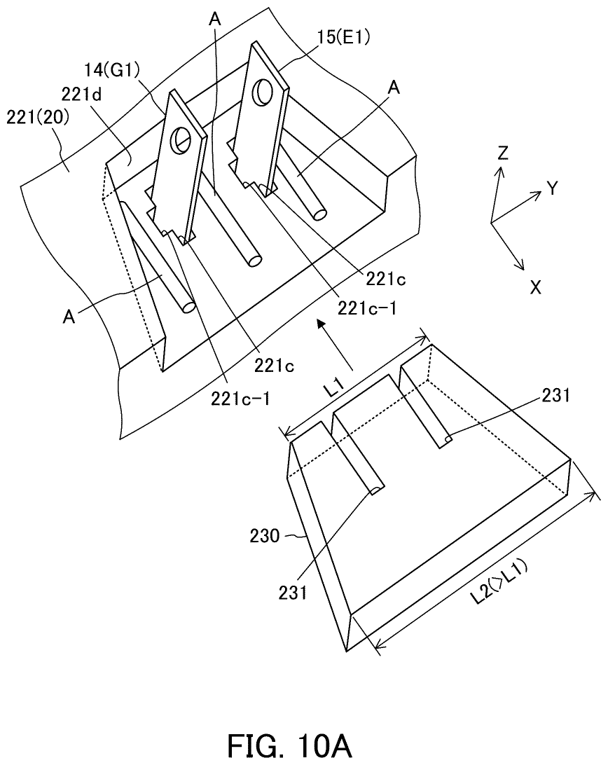

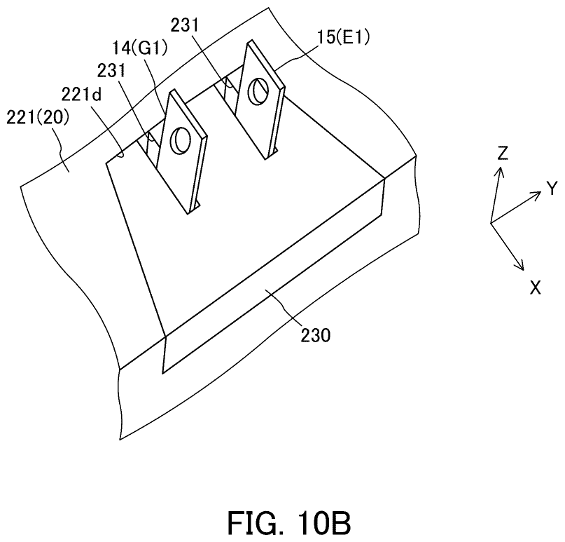

As illustrated in FIG. 10A (third modification), a case cutout 221d and an auxiliary block 230 of the case 20 (main body 221) may have trapezoidal shapes in plan view, and the width (Y direction) orthogonal to an insertion direction (X direction negative side) of the auxiliary block 230 into the case cutout 221d may become narrower toward the insertion direction (L1<L2). If the case cutout 221d and the auxiliary block 230 have the same shape, the entire auxiliary block 230 is housed in the case cutout 221d as illustrated in FIG. 10B.

Note that the main body 221 of the case 20 is also provided with case through-holes 221c having bulging parts 221c-1. Furthermore, as illustrated in FIG. 10A, the adhesive A is preferably disposed so as to sandwich each of the auxiliary terminals 14 to 17 in the case cutout 221d (bottom surface). Furthermore, the width (Y direction) that is orthogonal to the insertion direction and becomes narrower toward the insertion direction (X direction negative side) may be the width in the Z direction, and is not limited to the width in the Y direction. Furthermore, although the widths (Y direction) of the auxiliary block 230 and the case cutout 221d orthogonal to the insertion direction (X direction negative side) of the auxiliary block 230 become narrower toward the insertion direction (X direction negative side) in the third modification, the widths (at least one of the X direction and the Y direction) of the auxiliary block 30 and the recess part 21d illustrated in above-described FIG. 8A may become narrower toward the insertion direction (Z direction negative side).

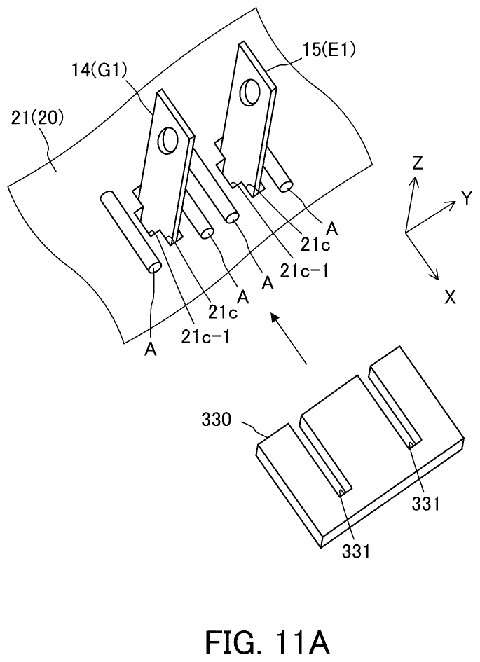

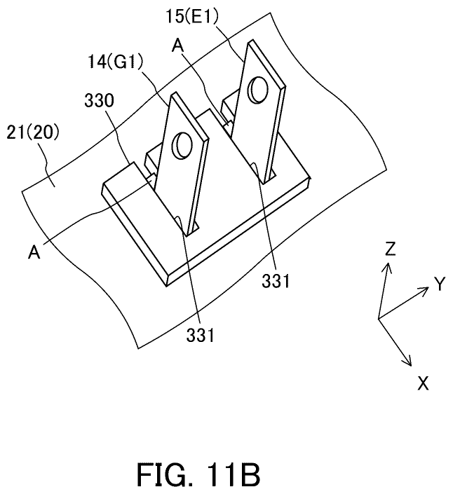

As illustrated in FIG. 11A (fourth modification), an auxiliary block 330 may be provided with block cutouts 331, and the case cutouts 121d and 221d may be omitted from the main body 21 (case 20). Furthermore, the main body 21 may be provided with the recess part 21d illustrated in FIG. 8A, and at least part of the auxiliary block 330 may be inserted into this recess part 21d. In this case, although the auxiliary block 330 protrudes from the main body 21 of the case 20 to the outside as illustrated in FIG. 11B, the block cutouts 331 are provided on the side surface of the auxiliary block 330 unlike the auxiliary block 30 including the block through-holes 31 illustrated in FIG. 7A, so that it is possible to insert the auxiliary blocks 330 from the sides of the auxiliary terminals 14 to 17 (toward the X direction negative side).

According to the above-described present embodiment, the semiconductor module 1 includes: the semiconductor elements 50; the wiring boards 60 on which these semiconductor elements 50 have been mounted; the auxiliary terminals 14 to 17 (an example of terminals) that have been electrically connected to these wiring boards 60; the case 20 that includes the case through-holes 21c into which these auxiliary terminals 14 to 17 have been inserted and that houses the semiconductor elements 50 and the wiring boards 60; the auxiliary blocks 30 that sandwich the root portions of the auxiliary terminals 14 to 17 protruding from the case through-holes 21c to the outside and are fixed to the case 20; and the adhesive A (an example of a sealing material) that closes these gaps between the auxiliary terminals 14 to 17 and the case through-holes 21c together with the auxiliary blocks 30 and adheres the auxiliary blocks 30 to the case 20.

Consequently, the auxiliary blocks 30 and the adhesive A can prevent an inflow of a corrosive gas (such as hydrogen sulfide or sulfuric acid gas) from the gaps between the auxiliary terminals 14 to 17 and the case through-holes 21c. Consequently, compared to the aspect where the dispenser that supplies the adhesive A to the gaps between the auxiliary terminals 14 to 17 and the case through-holes 21c is used, it is possible to avoid that it is difficult to approach the dispenser, or that failures such as unintentional adhesion of the adhesive A to the auxiliary terminals 14 to 17 and contact of the dispenser with the auxiliary terminals 14 to 17 in the process of handling the dispenser occur. Consequently, according to the present embodiment, it is possible to prevent the inflow of the corrosive gas from the gaps between the terminals (auxiliary terminals 14 to 17) and the case 20 (case through-holes 21c). Consequently, it is possible to suppress growth of corrosion products inside the semiconductor module 1, and improve the reliability of the semiconductor module 1. Furthermore, the semiconductor module 1 can be used in a highly corrosive environment, so that application of the semiconductor module 1 expands. Furthermore, it is possible to suppress deterioration of appearance due to exposure of the adhesive A. Furthermore, the adhesive A is more hardly peeled compared to an aspect where the adhesive A is supplied to the outside of the semiconductor module 1, so that it is possible to reliably prevent production of peeled-off waste and the inflow of the corrosive gas.

Furthermore, in the present embodiment, the auxiliary block 30 includes the block through-holes 31 into which the auxiliary terminals 14 to 17 have been inserted so as to sandwich the root portions.

Consequently, the auxiliary blocks 30 can close the gaps between the auxiliary terminals 14 to 17 and the case through-holes 21c in the surroundings of the block through-holes 31 and over the entire circumferences of the auxiliary terminals 14 to 17. Consequently, it is possible to further prevent the inflow of the corrosive gas.

Furthermore, in the present embodiment, the auxiliary block 30 includes the plurality of block through-holes 31 so as to sandwich the root portions.

Consequently, it is possible to close the gaps between the plurality of the auxiliary terminals 14 to 17 and the plurality of case through-holes 21c using the single auxiliary block 30. Consequently, the semiconductor module 1 can employ a simple configuration. Furthermore, it is possible to facilitate assembly of the auxiliary block 30 compared to the case where the auxiliary blocks 30 are disposed for the auxiliary terminals 14 to 17 close to each other.

Furthermore, according to the second to fourth modifications (FIGS. 9A to 11B) of the present embodiment, the auxiliary blocks 130, 230, and 330 include the block cutouts 131, 231, and 331 into which the auxiliary terminals 14 to 17 have been inserted.

Consequently, the auxiliary blocks 130, 230, and 330 can be inserted from the sides of the auxiliary terminals 14 to 17. Accordingly, it is possible to facilitate assembly of the auxiliary blocks 130, 230, and 330 compared to the case where the block through-holes 31 are provided.

Furthermore, according to the second to fourth modifications (FIGS. 9A to 11B) of the present embodiment, the auxiliary blocks 130, 230, and 330 include the plurality of block cutouts 131, 231, and 331.

Consequently, it is possible to close the gaps between the plurality of the auxiliary terminals 14 to 17 and the plurality of case through-holes 121c, 221c, and 21c using the single auxiliary blocks 130, 230, and 330. Consequently, the semiconductor module 1 can employ a simple configuration. Furthermore, it is possible to facilitate assembly of the auxiliary blocks 130, 230, and 330 compared to the case where the auxiliary blocks 130, 230, and 330 are disposed for the auxiliary terminals 14 to 17, respectively, close to each other.

Furthermore, according to the first modification (FIGS. 8A and 8B) of the present embodiment, the case 20 includes the recess part 21d into which at least part of the auxiliary block 30 has been inserted in the penetration direction (Z direction) in which the auxiliary terminals 14 to 17 penetrate the case through-holes 21c.

Consequently, it is possible to prevent the protrusion lengths of the auxiliary terminals 14 to 17 from the main body 21 from shortening due to protrusion of the auxiliary blocks 30 from the main body 21 of the case 20. Furthermore, it is also possible to make the adhesive A hardly leak to the outside of the main body 21.

Furthermore, according to the second and third modifications (FIGS. 9A to 10B) of the present embodiment, the case 20 (main bodies 121 and 221) includes the case cutouts 121d and 221d in which at least part of the auxiliary blocks 130 and 230 have been inserted in the direction (X direction negative side) intersecting the penetration direction (Z direction) in which the auxiliary terminals 14 to 17 penetrate the case through-holes 121c and 221c.

Consequently, it is possible to prevent the protrusion lengths of the auxiliary terminals 14 to 17 from the main bodies 121 and 221 from shortening due to protrusion of the auxiliary blocks 130 and 230 from the main bodies 121 and 221 of the case 20. Furthermore, in a case where the auxiliary blocks 130 and 230 include the block cutouts 131 and 231, it is possible to further facilitate assembly of the auxiliary blocks 130 and 230 by inserting the auxiliary blocks 130 and 230 from the sides of the auxiliary terminals 14 to 17 and the case 20. Furthermore, it is also possible to make the adhesive A hardly leak to the outside of the main bodies 121 and 221.

Furthermore, according to the third modification (FIGS. 10A and 10B) of the present embodiment, the widths (Y direction) of the case cutout 221d and the auxiliary block 230 of the case 20 (main body 221) orthogonal to the insertion direction (X direction negative side) of this auxiliary block 230 into the case cutout 221d become narrower toward the insertion direction (L1<L2).

Consequently, it is easy to insert the auxiliary block 230 into the case 20, so that it is possible to further facilitate assembly of the auxiliary block 230.

Furthermore, according to the present embodiment, the auxiliary terminals 14 to 17 include the protrusions 14a, 15a, 16a, 17a that protrude in the direction (the Y direction negative side or the Y direction positive side) intersecting the penetration direction (the Z direction) in which the auxiliary terminals 14 to 17 penetrate the case through-hole 21c, and the case through-holes 21c include the bulging parts 21c-1 that house the protrusions 14a, 15a, 16a, and 17a.

Consequently, the case through-holes 21c are provided with the bulging parts 21c-1, so that, even when the gaps between the auxiliary terminals 14 to 17 and the case through-holes 21c become larger, it is possible to close the gaps using the auxiliary blocks 30 and the adhesive A. Consequently, it is possible to further prevent the inflow of the corrosive gas.

Furthermore, in the present embodiment, the sealing material for closing the gaps between the auxiliary terminals 14 to 17 and the case through-holes 21c is the adhesive A for fixing the auxiliary block 30 to the case 20.

Consequently, it is possible to close the gaps between the auxiliary terminals 14 to 17 and the case through-holes 21c using the adhesive A for fixing the auxiliary blocks 30 to the case 20. Accordingly, it is possible to prevent an inflow of a corrosive gas with a simple configuration.

Furthermore, in the present embodiment, the terminals to be inserted into the case 20 and the auxiliary blocks 30 are the auxiliary terminals 14 to 17, and the semiconductor module 1 further includes the main terminals 11 to 13 electrically connected to the wiring boards 60.

By the way, inter-terminal intervals between the auxiliary terminals 14 to 17 in particular are narrow. Consequently, the gaps that are extremely difficult to close even using the above-described dispenser or the like can be closed using the auxiliary blocks 30.

The semiconductor module according to the present invention is not limited to the embodiment described above, and various changes, substitutions, and modifications may be made without departing from the spirit of the technical concept. Furthermore, if the technical idea can be achieved in another manner due to the progress of the technology or by another derived technology, the technical idea may be carried out by using the manner. Therefore, the claims cover all embodiments that may be included within the scope of the technical idea.

Hereinafter, some inventions described in the specification and drawings of the present application will be additionally described.

### <Supplementary Note 1>

A semiconductor module including:
a semiconductor element;
a wiring board on which the semiconductor element has been mounted;
a terminal that has been electrically connected to the wiring board;
a case that includes a case through-hole into which the terminal has been inserted and houses the semiconductor element and the wiring board;
an auxiliary block that sandwiches a root portion of the terminal protruding from the case through-hole to an outside, and is fixed to the case; and
a sealing material that closes a gap between the terminal and the case through-hole together with the auxiliary block, and adheres the auxiliary block to the case.

### <Supplementary Note 2>

The semiconductor module described in supplementary note 1, in which
the auxiliary block includes a block through-hole into which the terminal has been inserted so as to sandwich the root portion.

### <Supplementary Note 3>

The semiconductor module described in supplementary note 2, in which
the auxiliary block includes a plurality of the block through-holes.

### <Supplementary Note 4>

The semiconductor module described in supplementary note 1, in which
the auxiliary block includes a block cutout into which the terminal has been inserted so as to sandwich the root portion.

### <Supplementary Note 5>

The semiconductor module described in supplementary note 4, in which
the auxiliary block includes a plurality of the block cutouts.

### <Supplementary Note 6>

The semiconductor module described in any one of supplementary notes 1 to 5, in which
the case includes a recess part into which at least part of the auxiliary block has been inserted in a penetration direction in which the terminal penetrates the case through-hole.

### <Supplementary Note 7>

The semiconductor module described in any one of supplementary notes 1 to 6, in which
the case includes a case cutout into which at least part of the auxiliary block has been inserted in a direction intersecting a penetration direction in which the terminal penetrates the case through-hole.

### <Supplementary Note 8>

The semiconductor module described in supplementary note 7, in which
widths of the case cutout and the auxiliary block orthogonal to an insertion direction of the auxiliary block into the case cutout become narrower toward the insertion direction.

### <Supplementary Note 9>

The semiconductor module described in any one of supplementary notes 1 to 8, in which
the terminal includes a protrusion that protrudes in a direction intersecting a penetration direction that penetrates the case through-hole, and
the case through-hole includes a bulging part that houses the protrusion.

### <Supplementary Note 10>

The semiconductor module described in any one of supplementary notes 1 to 9, in which
the sealing material is an adhesive for fixing the auxiliary block to the case.

### <Supplementary Note 11>

The semiconductor module described in any one of supplementary notes 1 to 10, in which
the terminal is an auxiliary terminal, and
the semiconductor module further includes a main terminal that has been electrically connected to the wiring board.

As described above, the present invention has an effect that it is possible to prevent an inflow of a corrosive gas from gaps between terminals and a case, and is particularly useful for industrial or electrical inverter devices.

What is claimed is:

1. A semiconductor module, comprising:
a semiconductor element;
a wiring board on which the semiconductor element is mounted;
a terminal that is electrically connected to the wiring board;
a case that houses the semiconductor element and the wiring board, the case including a case through-hole into which the terminal is inserted such that a root portion of the terminal protrudes from the case through-hole outside the case;
an auxiliary block that sandwiches the root portion of the terminal with the case to fix the terminal to the case; and
a sealing material that closes a gap between the terminal and the case through-hole together with the auxiliary block and adheres the auxiliary block to the case.

2. The semiconductor module according to claim 1, wherein
the auxiliary block includes a block through-hole into which the terminal is inserted so as to sandwich the root portion with the case.

3. The semiconductor module according to claim 2, wherein
the auxiliary block includes a plurality of the block through-holes.

4. The semiconductor module according to claim 1, wherein
the auxiliary block includes a block cutout into which the terminal is inserted so as to sandwich the root portion with the case.

5. The semiconductor module according to claim 4, wherein
the auxiliary block includes a plurality of the block cutouts.

6. The semiconductor module according to claim 1, wherein
the case includes a recess part into which at least part of the auxiliary block is inserted in a penetration direction in which the terminal passes through the case through-hole.

7. The semiconductor module according to claim 1, wherein
the case includes a case cutout into which at least part of the auxiliary block is inserted in a direction intersecting a penetration direction in which the terminal passes through the case through-hole.

8. The semiconductor module according to claim 7, wherein
widths of the case cutout and the auxiliary block, in a direction which is orthogonal to an insertion direction of the auxiliary block into the case cutout, decreases toward the insertion direction.

9. The semiconductor module according to claim 1, wherein
the terminal includes a protrusion that protrudes in a direction intersecting a penetration direction in which the terminal passes through the case through-hole, and
the case through-hole includes a bulging part that accommodates the protrusion.

10. The semiconductor module according to claim 1, wherein
the sealing material is an adhesive for fixing the auxiliary block to the case.

11. The semiconductor module according to claim 1, wherein
the terminal is an auxiliary terminal, and
the semiconductor module further includes a main terminal that is electrically connected to the wiring board.
